(19) United States
(12) Patent Application Publication
(10) Pub. No.: US 2024/0395633 A1
(43) Pub. Date: Nov. 28, 2024

(54) ISOTHERMAL HETEROGENOUS WAFER BONDING SUBSTRATE REMOVAL

(71) Applicant: WAVEFRONT HOLDINGS, LLC, Basking Ridge, NJ (US)

(72) Inventor: Jie YAO, Basking Ridge, NJ (US)

(21) Appl. No.: 18/658,325

(22) Filed: May 8, 2024

Related U.S. Application Data
(60) Provisional application No. 63/468,190, filed on May 22, 2023.

(51) Int. Cl. H01L 21/8258

(52) U.S. Cl. CPC H01L 21/8258

(57) ABSTRACT

Disclosed is method of wafer-to-wafer bonding between at least one pair of semiconductor wafers having different substrate materials, and subsequent removal of a substrate of at least one wafer of the at least one pair of semiconductor wafers. In the embodiment, the method includes bringing at least one pair of semiconductor wafers of different substrate materials into direct physical contact at a temperature within ±10° C. of a bonding temperature required to bond the at least one pair of semiconductor wafers to one another, to thereby bond the at least one pair of semiconductor wafers to one another. The method further includes removing from at least one semiconductor wafer of the at least one pair of semiconductor wafers at least 90% of the substrate thickness over at least 90% of the area of the at least one semiconductor wafer at a temperature within ±10° C. of the bonding temperature required to bond the at least one pair of semiconductor wafers to one another.

### STATEMENT REGARDING FEDERALLY SPONSORED RESEARCH OR DEVELOPMENT

This invention was made in part with Government support under contracts FA9453-22-C-A011 and W9113M22C0080 awarded by the U.S. Department of Defense. The Government has certain rights in the invention.

### CROSS-REFERENCE TO RELATED APPLICATIONS

This application refers to and claims the priority date of U.S. provisional patent 63468190 entitled “HighEgPT&IsothermalBond” filed on 22 May 2023 with EFS ID 48040488, the disclosure of which is hereby incorporated by reference in its entirety.

### FIELD OF THE EMBODIMENTS

The embodiments relate to heterogenous wafer to wafer bonding of semiconductor wafers of different substrate materials.

### DESCRIPTION OF RELATED ART

Although silicon wafer to silicon wafer bonding is a mature technology in mass manufacturing, the state of the art for bonding heterogeneous materials is still limited to dice. This invention teaches the heterogenous wafer to wafer bonding of semiconductor wafers of different substrate materials at the whole wafer scale.

### SUMMARY OF THE EMBODIMENTS

One embodiment disclosed herein relates to a method of wafer-to-wafer bonding between at least one pair of semiconductor wafers having different substrate materials, and subsequent removal of a substrate of at least one wafer of the at least one pair of semiconductor wafers. In the embodiment, the method includes bringing at least one pair of semiconductor wafers of different substrate materials into direct physical contact at a temperature within ±10° C. of a bonding temperature required to bond the at least one pair of semiconductor wafers to one another, to thereby bond the at least one pair of semiconductor wafers to one another. The method further includes removing from at least one semiconductor wafer of the at least one pair of semiconductor wafers at least 90% of the substrate thickness over at least 90% of the area of the at least one semiconductor wafer at a temperature within ±10° C. of the bonding temperature required to bond the at least one pair of semiconductor wafers to one another. In accordance with this embodiment, the method provides direct physical contact between the at least one pair of semiconductor wafers and prohibits and excludes subsequent heating or annealing or cooling outside the temperature range of ±10° C. of the bonding temperature of the at least one pair of semiconductor wafers before the removal is completed. In another embodiment, the different substrate materials are formed from constituent atoms that are at least 90% different from one another.

### BRIEF DESCRIPTION OF THE FIGURE

FIGS. 1 through 4 illustrate embodiments of an isothermal heterogeneous wafer-to-wafer bonding and substrate removal process not drawn to scale. The figures illustrate a method of bonding a pair of semiconductor wafers of different substrate materials and subsequent removal of most of the substrate of at least one wafer of the pair of wafers.

FIG. 1 illustrates an embodiment of bonding focal plane array (FPA) epitaxial wafers on indium phosphide (InP) substrates to readout integrated circuit (ROIC) wafer on silicon (Si) substrate at 20˜22° C. temperature range.

FIG. 2 illustrates an embodiment of applying perfluoropolyether (PFPE) inert grease to seal the exposed wafer bonding interfaces at 20˜22° C.

FIG. 3 illustrates an embodiment of etching InP substrates in an acid comprising > 1/10 weight of HCl stopping at arsenide epitaxial layers inside the FPA epitaxial wafers at 20˜22° C.

FIG. 4 illustrates another embodiment of dissolving and removing the PFPE inert grease in PFPE solvent, and annealing the bonded wafer pairs above 20˜22° C.

### DETAILED DESCRIPTION

In this disclosure, two processes are considered to be “in sequential temporal order” if and only if the first of the two processes is performed and completed before the second process, and the second of the two processes is started and performed after the first process with optional process(es) allowable between the first and second processes. In this disclosure, two processes are considered to be “consecutive” if and only if the first and second processes are performed back to back with no break between them, which prohibits any other process or break between the first and second processes.

Sequentiality and consecutiveness as defined above do not require or imply each other.

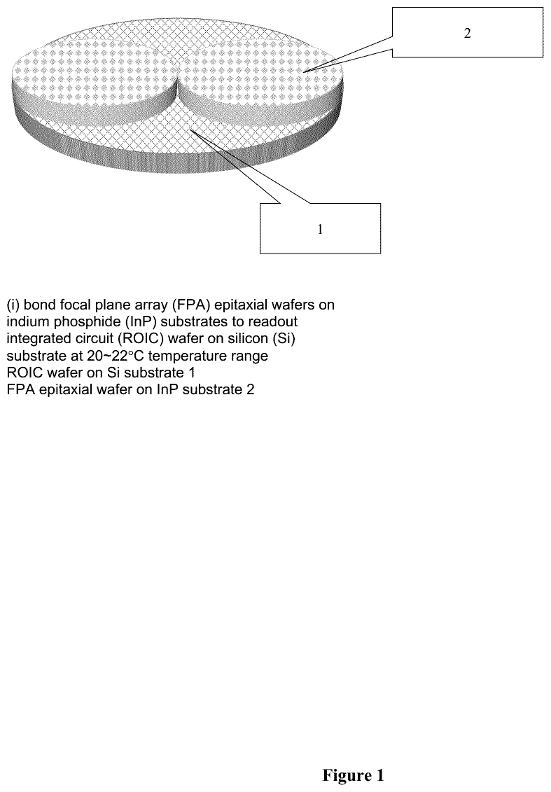

One embodiment shown in FIGS. 1 through 4 (not drawn to scale) illustrates an isothermal heterogeneous wafer-to-wafer bonding and substrate removal process involving a method of bonding a pair of semiconductor wafers of different substrate materials and subsequent removal of most of the substrate of at least one wafer of the pair of wafers. In this specific embodiment, the method of wafer-to-wafer bonding between at least one pair of semiconductor wafers having different substrate materials, and subsequent substantial removal of a substrate of at least one wafer of the at least one pair of semiconductor wafers, may include the following five steps (i), (ii), (iii), (iv) and (v) in sequential temporal order.

Steps (i) and (iii) are mandatory. Steps (ii), (iv) and (v) are optional. FIG. 1 shows the mandatory step (i) to bond focal plane array (FPA) epitaxial wafers on indium phosphide (InP) substrates to readout integrated circuit (ROIC) wafer on silicon (Si) substrate at 20˜22° C. temperature range. The mandatory step (i) brings at least one pair of semiconductor wafers of different substrate materials into direct physical contact at a temperature within ±10° C., ±3° C. or ±1° C. of a bonding temperature 21° C. required to bond the at least one pair of semiconductor wafers to one another, to thereby bond the at least one pair of semiconductor wafers to one another.

The bonding temperature required to bond the at least one pair of semiconductor wafers to one another is between 0° C. and 100° C., inclusive. The bonding temperature required to bond the at least one pair of semiconductor wafers to one another is between 20° C. and 22° C., inclusive. A first wafer of the at least one pair of semiconductor wafers may comprise a focal plane array (FPA) epitaxial wafer on InP substrate 2, and/or a second wafer of the at least one pair of semiconductor wafers may comprise a readout integrated circuit (ROIC) wafer on Si substrate 1. This first step (i) provides direct physical contact between the at least one pair of semiconductor wafers and prohibits and excludes subsequent heating or annealing or cooling outside the temperature range of ±10° C., ±3° C. or ±1° C. of the bonding temperature 21° C. of the at least one pair of semiconductor wafers before step (iii) completes. The different substrate materials of ROIC wafer 1 and FPA wafer 2 are comprised of constituent atoms that are at least 90% different from one another.

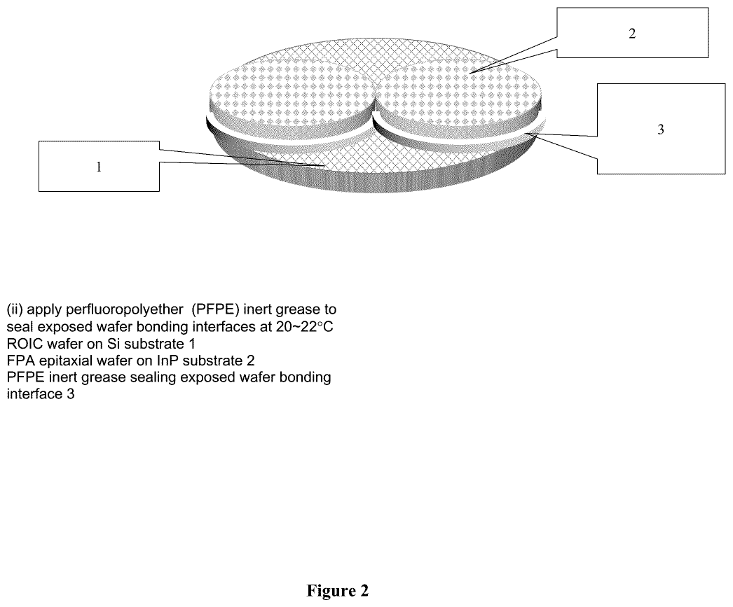

FIG. 2 shows the optional step (ii) to apply perfluoropolyether (PFPE) inert grease to seal exposed wafer bonding interfaces at 20˜22° C. Step (ii) is the additional processing between step (i) and step (iii) at a temperature within ±10° C., ±3° C. or ±1° C. of the bonding temperature 21° C. The PFPE inert grease 3 seals the exposed wafer bonding interface formed between the ROIC wafer on Si substrate 1 and the FPA epitaxial wafer on InP substrate 2.

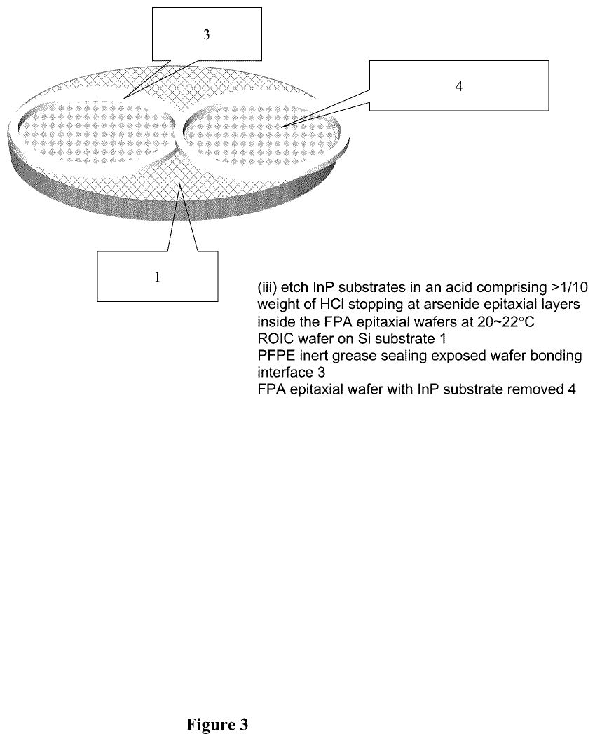

FIG. 3 shows the mandatory step (iii) to etch InP substrates in an acid comprising > 1/10 weight of HCl stopping at arsenide epitaxial layers inside the FPA epitaxial wafers at 20˜22° C. This mandatory step removes from at least one semiconductor wafer of the at least one pair of semiconductor wafers at least 90% of the substrate thickness over at least 90% of the area of the at least one semiconductor wafer at a temperature within ±10° C., ±3° C. or ±1° C. of the bonding temperature 21° C. required to bond the at least one pair of semiconductor wafers to one another.

In one embodiment, at least 99% of the substrate thickness is removed. The entirety of the substrate thickness is removed, leaving only epitaxial portions of the original semiconductor wafer. One wafer substrate of the at least one pair of semiconductor wafers is InP with or without dopant, and the other wafer substrate of the at least one pair of semiconductor wafers is Si with or without dopant. The entire thickness of the doped or undoped InP substrate is removed in step (iii) by an acid comprising no less than 1% or 10% by weight of hydrochloric acid (HCl), and the InP substrate removal etch stops at an essentially arsenide epitaxial layer. The PFPE inert grease 3 still seals the exposed wafer bonding interface formed between the ROIC wafer on Si substrate 1 and the FPA epitaxial wafer with InP substrate substantially removed 4.

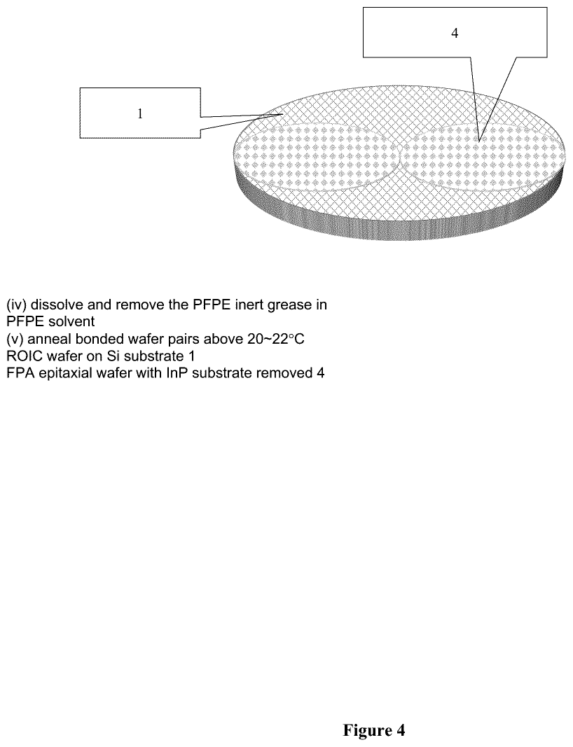

FIG. 4 shows the optional step (iv) to dissolve and remove the PFPE inert grease in PFPE solvent and the optional step (v) to anneal bonded wafer pairs above 20˜22° C. The at least one pair of semiconductor wafers comprising the at least one semiconductor wafer whose substrate was removed in step (iii) is heated to and/or annealed at a temperature more than 10° C. above the bonding temperature 21° C. after completion of steps (i) and (iii). The at least one pair of semiconductor wafers comprising the at least one semiconductor wafer whose substrate was removed in step (iii) is heated to and/or annealed at a temperature more than 10° C. above the bonding temperature 21° C. after completion of step (i), the additional processing step (ii) and step (iii).

The result is the FPA epitaxial wafer with InP substrate substantially removed 4 wafer-to-wafer bonded to the ROIC wafer on Si substrate 1. The at least one pair of semiconductor wafers comprises a total of no less than 107, 108, 109 or 1010 pixels and no less than 107, 108, 109 or 1010 readout unit cells. The method bonds multiple wafers of a first type to a single wafer of a second type, and each substrate of the multiple wafers of the first type is substantially removed.

B. F. Levine & A. R. Hawkins & S. Hiu & B. J. Tseng & J. P. Reilley & C. A. King & L. A. Gruezke & R. W. Johnson & D. R. Zolnowski & J. E. Bowers stated in their paper “Characterization of wafer bonded photodetectors fabricated using various annealing temperatures and ambients”: “In order to better understand the bonding process and the optimum fusion conditions, we have performed a systematic variation of the bonding temperature (T=650, 550, and 475° C.) and the surrounding flowing gas ambient (H2,N2, and forming gas consisting of 10% H2+90% N2) . . . . These wafers were fused in an oven using the following conditions: 650° C. in H2, 650° C. in N2; 650° C. in forming gas (10% H2+90% N2), 550° C. in H2 and 475° C. in H2. After bonding, the InP substrate and the InGaAs etch stop layer were removed” at unspecified temperature. Since most InP etches do not exceed 300° C., their bonding process at ≥475° C. and their substrate removal process at <300° C. are not performed within the temperature range required by this patent application. Refer to B. F. Levine & A. R. Hawkins & S. Hiu & B. J. Tseng & J. P. Reilley & C. A. King & L. A. Gruczke & R. W. Johnson & D. R. Zolnowski & J. E. Bowers, “Characterization of wafer bonded photodetectors fabricated using various annealing temperatures and ambients”, Appl. Phys. Lett., 15 Sep. 1997; 71 (11): 1507-1509.

### REFERENCES

Deptuch, G. & Heintz, U. & Johnson, Mo & Kenney, C. & Lipton, R. & Narian, M. & Parker, Sherwood & Shenai, A. & Spiegel, Leonard & Thom, J. & Ye, Zhaoting, “3D Technologies for Large Arca Trackers”, Whitepaper Submitted to Snowmass 2013, Jul. 17, 2013.
Kagawa, Y. & Fujii, N. & Aoyagi, K. & Kobayashi, Y. & Nishi, S. & Todaka, N. & Takeshita, S. & Taura, J. & Takahashi, H. & Nishimura, Y. & Tatani, K. & Kawamura, M. & Nakayama, H. & Ohno, K. & Iwamoto, H. & Kadomura, S. & Hirayama, T., “An Advanced CuCu Hybrid Bonding For Novel Stacked CMOS Image Sensor”, 2018 IEEE 2nd Electron Devices Technology and Manufacturing Conference (EDTM), Kobe, Japan, 2018, pp. 65-67, doi: 10.1109/EDTM.2018.8421453.
Deptuch, Grzegorz & Demarteau, Marcel & Hoff, James & Lipton, Ronald & Shenai, Alpana & Trimpl, Marcel & Yarema, Raymond & Zimmerman, Tom, “Vertically integrated circuits at formilab,” 2009 IEEE Nuclear Science Symposium Conference Record (NSS/MIC), Orlando, FL, USA, 2009, pp. 1907-1915, doi: 10.1109/NSSMIC.2009.5402167.
Paul Enquist, “3D integration applications for low temperature direct bond technology”, 2014 4th IEEE International Workshop on Low Temperature Bonding for 3D Integration (LTB-3D), Tokyo, Japan, 2014, pp. 8-8, doi: 10.1109/LTB-3D.2014.6886147.
Lhostis, S. & Farcy, A. & Deloffre, E. & Lorut, F. & Mermoz, S. & Henrion, Y. & Berthier, L. & Bailly, F. & Scevola, D. & Guyader, F. & Gigon, F. & Besset, C. & Pellissier, S. & Gay, L. & Hotellier, N. & Le Berrigo, A.-L. & Moreau, S. & Balan, V. & Fournel, F. & Jouve, A. & Cheramy, S. & Arnoux, M. & Rebhan, B. & Maier, G. A. & Chitu, L., “Reliable 300 mm Wafer Level Hybrid Bonding for 3D Stacked CMOS Image Sensors”, 2016 IEEE 66th Electronic Components and Technology Conference (ECTC), Las Vegas, NV, USA, 2016, pp. 869-876, doi: 10.1109/ECTC.2016.202.
Cheramy, S. & Jouve, A. & Arnaud, L. & Fenouillet-Beranger, C. & Batude, P. & Vinet, M., “Towards high density 3D interconnections,” 2016 IEEE International 3D Systems Integration Conference (3DIC), San Francisco, CA, USA, 2016, pp. 1-5, doi: 10.1109/3DIC.2016.7970037.
Kagawa, Y. & Fujii, N. & Aoyagi, K. & Kobayashi, Y. & Nishi, S. & Todaka, N. & Takeshita, S. & Taura, J. & Takahashi, H. & Nishimura, Y. & Tatani, K. & Kawamura, M. & Nakayama, H. & Nagano, T. & Ohno, K. & Iwamoto, H. & Kadomura, S. & Hirayama, T., “Novel stacked CMOS image sensor with advanced Cu2Cu hybrid bonding,” 2016 IEEE International Electron Devices Meeting (IEDM), San Francisco, CA, USA, 2016, pp. 8.4.1-8.4.4, doi: 10.1109/IEDM.2016.7838375.
Moreau, Stephane & Bouchu, David & Balan, Viorel & Berrigo, Anne-Lise Le & Jouve, Amandine & Henrion, Yann & Besset, Carine & Scevola, Daniel & Lhostis, Sandrine & Guyader, François & Deloffre, Emilie & Mermoz, Sebastien & Pruvost, Julien, “Mass Transport-Induced Failure of Hybrid Bonding-Based Integration for Advanced Image Sensor Applications,” 2016 IEEE 66th Electronic Components and Technology Conference (ECTC), Las Vegas, NV, USA, 2016, pp. 1940-1945, doi: 10.1109/ECTC.2016.27.
Beyne, Eric & Kim, Soon-Wook & Peng, Lan & Heylen, Nancy & De Messemaeker, Joke & Okudur, Oguzhan Orkut & Phommahaxay, Alain & Kim, Tac-Gon & Stucchi, Michele & Velenis, Dimitrios & Miller, Andy & Beyer, Gerald, “Scalable, sub 2?m pitch, Cu/SiCN to Cu/SiCN hybrid wafer-to-wafer bonding technology,” 2017 IEEE International Electron Devices Meeting (IEDM), San Francisco, CA, USA, 2017, pp. 32.4.1-32.4.4, doi: 10.1109/IEDM.2017.8268486.
Jourdon, J. & Moreau, S. & Bouchu, D. & Lhostis, S. & Bresson, N. & Guiheux, D. & Bencyton, R. & Renard, S. & Fremont, H., “Effect of passivation annealing on the electromigration properties of hybrid bonding stack,” 2017 IEEE International Reliability Physics Symposium (IRPS), Monterey, CA, USA, 2017, pp. MR-3.1-MR-3.6, doi: 10.1109/IRPS.2017.7936378.
Venezia, V. C. & Shih, C. & Yang, W. Z. & Zang, Y. & Lin, Z. & Grant, L. A. & Rhodes, H., 2017, “1.0 um Pixel Improvements With Hybrid Bond Stacking Technology,” Proceedings of International Image Sensor Workshop, Hiroshima, Japan, May 30-June 2, R03, pp. 8-11.
Ichiro Yonenaga, “Hardness, Yield Strength, and Dislocation Velocity in Elemental and Compound Semiconductors”, MATERIALS TRANSACTIONS, 2005, Volume 46, Issue 9, Pages 1979-1985, Released on J-STAGE Nov. 14, 2005, Online ISSN 1347-5320, Print ISSN 1345-9678, https://doi.org/10.2320/matertrans.46.1979, https://www.jstage.jst.go.jp/article/matertrans/46/9/46_9_1979/_article/-char/en
Liang Wang & Fountain, Gill & Bongsub Lec & Guilian Gao & Uzoh, Cyprian & McGrath, Scott & Enquist, Paul & Arkalgud, Sitaram & Mirkarimi, Laura, “Direct Bond Interconnect (DBI®) for fine-pitch bonding in 3D and 2.5D integrated circuits,” 2017 Pan Pacific Microelectronics Symposium (Pan Pacific), Kauai, HI, 2017, pp. 1-6.
Dragoi, Viorel & Mittendorfer, G. & Floetgen, Christoph & Dussault, D. & Wagenleitner, T., “Aligned fusion wafer bonding for CMOS-MEMS and 3D wafer-level integration applications”, Romanian Journal of Information Science and Technology, 14, 356, 2011.
Cheng-Ta Ko & Kuan-Neng Chen, “Low temperature bonding technology for 3D integration”, Microelectronics Reliability, Volume 52, Issue 2, 2012, Pages 302-311, ISSN 0026-2714. https://doi.org/10.1016/j.microrel.2011.03.038 https://www.sciencedirect.com/science/article/pii/S0026271411001211
Peter Ramm (Editor) & James Jian-Qiang Lu (Editor) & Maaike M. V. Taklo (Editor), “Handbook of Wafer Bonding”, First published: 11 Jan. 2012, Print ISBN: 9783527326464, Online ISBN: 9783527644223, February 2012 425 Pages, DOI: 10.1002/9783527644223, Copyright @ 2012 Wiley?VCH Verlag Gmbh & Co. KGaA
Panigrahy, A. K. & Chen, K., “Low Temperature Cu—Cu Bonding Technology in Three-Dimensional Integration: An Extensive Review.” ASME. J. Electron. Packag. March 2018; 140 (1): 010801. https://doi.org/10.1115/1.4038392
Gao, Guilian & Mirkarimi, Laura & Workman, Thomas & Fountain, Gill & Theil, Jeremy & Guevara, Gabe & Liu, Ping & Lec, Bongsub & Mrozek, Pawel & Huynh, Michael & Rudolph, Catharina & Werner, Thomas & Hanisch, Anke, “Low Temperature Cu Interconnect with Chip to Wafer Hybrid Bonding,” 2019 IEEE 69th Electronic Components and Technology Conference (ECTC), Las Vegas, NV, USA, 2019, pp. 628-635, doi: 10.1109/ECTC.2019.00100.
Stine, B. E. & Boning, D. S. & Chung, J. E. & Camilletti, L. & Kruppa, F. & Equi, E. R. & Loh, W. & Prasad, S. & Muthukrishnan, M. & Towery, D. & Berman, M. & Kapoor, A., “The physical and electrical effects of metal-fill patterning practices for oxide chemical-mechanical polishing processes,” in IEEE Transactions on Electron Devices, vol. 45, no. 3, pp. 665-679, March 1998, doi: 10.1109/16.661228.
Manda, S. & Matsumoto, R. & Saito, S. & Maruyama, S. & Minari, H. & Hirano, T. & Takachi, T. & Fujii, N. & Yamamoto, Y. & Zaizen, Y. & Hirano, T. & Iwamoto, H., “High-definition Visible-SWIR InGaAs Image Sensor using Cu—Cu Bonding of III-V to Silicon Wafer,” 2019 IEEE International Electron Devices Meeting (IEDM), San Francisco, CA, USA, 2019, pp. 16.7.1-16.7.4, doi: 10.1109/IEDM19573.2019.8993432.
D. Pasquariello & K. Hjort, “Plasma-assisted InP-to-Si low temperature wafer bonding,” in IEEE Journal of Selected Topics in Quantum Electronics, vol. 8, no. 1, pp. 118-131, January-February 2002, doi: 10.1109/2944.991407.
Gao, Guilian & Workman, Thomas & Mirkarimi, Laura & Fountain, Gill & Theil, Jeremy & Guevara, Gabe & Uzoh, Cyprian & Lec, Bongsub & Liu, Ping & Mrozek, Pawel, “Chip to Wafer Hybrid Bonding with Cu Interconnect: High Volume Manufacturing Process Compatibility Study,” 2019 International Wafer Level Packaging Conference (IWLPC), San Jose, CA, USA, 2019, pp. 1-9, doi: 10.23919/IWLPC.2019.8913877.
Lu, M. “Advancement of Chip Stacking Architectures and Interconnect Technologies for Image Sensors.” ASME. J. Electron. Packag. 24 Sep. 2021, June 2022; 144 (2): 020801. https://doi.org/10.1115/1.4052069
Pauchard, A. & Pan, Z. & Bitter, M. & Kang, Y. & Mages, P. & Hummel, S. G. & Yu, P. K. L. & Lo, Y. H., “Wafer bonding for the fabrication of high-performance photodetectors: a mature technology?”, The 15th Annual Meeting of the IEEE Lasers and Electro-Optics Society,
Glasgow, U K, 2002, pp. 677-678 vol. 2, doi: 10.1109/LEOS.2002.1159487.
B. F. Levine & A. R. Hawkins & S. Hiu & B. J. Tseng & J. P. Reilley & C. A. King & L. A. Gruezke & R. W. Johnson & D. R. Zolnowski & J. E. Bowers, “Characterization of wafer bonded photodetectors fabricated using various annealing temperatures and ambients”, Appl. Phys. Lett., 15 Sep. 1997; 71 (11): 1507-1509. https://doi.org/10.1063/1.119950

What is claimed is:

1. A method of wafer-to-wafer bonding between at least one pair of semiconductor wafers having different substrate materials, and subsequent removal of a substrate of at least one wafer of the at least one pair of semiconductor wafers, comprising in sequential temporal order:
a) bringing at least one pair of semiconductor wafers of different substrate materials into direct physical contact at a temperature within ±10° C. of a bonding temperature required to bond the at least one pair of semiconductor wafers to one another, to thereby bond the at least one pair of semiconductor wafers to one another; and
b) removing from at least one semiconductor wafer of the at least one pair of semiconductor wafers at least 90% of the substrate thickness over at least 90% of the area of the at least one semiconductor wafer at a temperature within ±10° C. of the bonding temperature required to bond the at least one pair of semiconductor wafers to one another,
wherein a) provides direct physical contact between the at least one pair of semiconductor wafers and prohibits and excludes subsequent heating or annealing or cooling outside the temperature range of ±10° C. of the bonding temperature of the at least one pair of semiconductor wafers before b) completes, and
wherein the different substrate materials are comprised of constituent atoms that are at least 90% different from one another.

2. The method according to claim 1 further comprising additional processing between a) and b) at a temperature within ±10° C. of the bonding temperature.

3. The method according to claim 1 wherein the temperature is within ±3° C. of the bonding temperature.

4. The method according to claim 1 wherein the temperature is within ±1° C. of the bonding temperature.

5. The method according to claim 1 wherein the at least one pair of semiconductor wafers comprising the at least one semiconductor wafer whose substrate was removed in b) is heated to and/or annealed at a temperature more than 10° C. above the bonding temperature after completion of a) and b).

6. The method according to claim 2 wherein the at least one pair of semiconductor wafers comprising the at least one semiconductor wafer whose substrate was removed in b) is heated to and/or annealed at a temperature more than 10° C. above the bonding temperature after completion of a), the additional processing and b).

7. The method according to claim 1 wherein at least 99% of the substrate thickness is removed.

8. The method according to claim 1 wherein the entirety of the substrate thickness is removed, leaving only epitaxial portions of the original semiconductor wafer.

9. The method according to claim 1 wherein the at least one pair of semiconductor wafers comprises a total of no less than 107 pixels and no less than 107 readout unit cells.

10. The method according to claim 1 wherein the at least one pair of semiconductor wafers comprises a total of no less than 108 pixels and no less than 108 readout unit cells.

11. The method according to claim 1 wherein the at least one pair of semiconductor wafers comprises a total of no less than 109 pixels and no less than 109 readout unit cells.

12. The method according to claim 1 wherein the at least one pair of semiconductor wafers comprises a total of no less than 1010 pixels and no less than 1010 readout unit cells.

13. The method according to claim 1 wherein one wafer substrate of the at least one pair of semiconductor wafers is InP with or without dopant, and the other wafer substrate of the at least one pair of semiconductor wafers is Si with or without dopant, and wherein the entire thickness of the doped or undoped InP substrate is removed in b) by an acid comprising no less than 1% by weight of hydrochloric acid (HCl).

14. The method according to claim 13 wherein the InP substrate removal etch stops at an essentially arsenide epitaxial layer.

15. The method according to claim 13 wherein the acid comprises no less than 10% by weight of hydrochloric acid (HCl).

16. The method according to claim 15 wherein the InP substrate removal etch stops at an essentially arsenide epitaxial layer.

17. The method according to claim 1, wherein the method bonds multiple wafers of a first type to a single wafer of a second type.

18. The method according to claim 17, wherein each substrate of the multiple wafers of the first type is substantially removed.

19. The method according to claim 1, wherein a first wafer of the at least one pair of semiconductor wafers comprises a focal plane array (FPA), and/or a second wafer of the at least one pair of semiconductor wafers comprises a readout integrated circuit (ROIC).

20. The method according to claim 1 wherein the bonding temperature required to bond the at least one pair of semiconductor wafers to one another is between 0° C. and 100° C., inclusive.

21. The method according to claim 1 wherein the bonding temperature required to bond the at least one pair of semiconductor wafers to one another is between 20° C. and 22° C., inclusive.
